(19) United States
(12) Patent Application Publication
(10) Pub. No.: US 2017/0151598 A1
(43) Pub. Date: Jun. 1, 2017

(54) Imprinting Metallic Substrates at Hot Working Temperatures

(71) Applicant: Agency for Science, Technology and Research, Singapore (SG)

(72) Inventors: Xue LI, Singapore (SG); Saifullah MSM, Singapore (SG); Yee Chong LOKE, Singapore (SG); Karen CHONG, Singapore (SG)

(73) Assignee: Agency for Science, Technology and Research, Singapore (SG)

(21) Appl. No.: 15/313,854

(22) PCT Filed: May 29, 2015
(86) PCT No.: PCT/SG2015/050133

§ 371 Date: Nov. 23, 2016

(30) Foreign Application Priority Data
May 29, 2014 (SG) 10201402732P

(51) Int. Cl. B21D 22/02; G03F 7/00; C22C 13/02; C22C 30/04; B81C 1/00; C22C 12/00

(52) U.S. Cl. CPC B21D 22/022; B81C 1/0046; C22C 12/00; C22C 13/02; C22C 30/04; G03F 7/0002

(57) ABSTRACT

The present invention relates to a method of forming an imprint on a metal substrate. The method comprises a step of providing a mold having a defined imprint surface pattern in the nano-sized or micro-sized range and a step of pressing the metal substrate against the mold at hot-working temperature to form a nano-sized or micro-sized imprint thereon.

### TECHNICAL FIELD

The present invention generally relates to a method for making an imprint on a metal substrate. The present invention also relates to metals substrates imprinted using the method.

### BACKGROUND ART

The assembly of three dimensional structures on metals is of particular interest in the field of material science and engineering. For instance, the surface of metals could be patterned with micro- or nano-structures in order to provide desired physical properties, e.g., optical or hydroscopic properties. Accordingly, a number of methods for fabricating and assembling such structures have been proposed in the state of the art.

A known method contemplates the provision of micro-miniaturizing metallic parts via metal injection moulding (MIM). MIM may be useful for forming intricate 3-dimensional structures, which are otherwise difficult to make using conventional metal fabrication techniques (e.g., machining). In addition, MIM is often more cost effective for structuring expensive metals, as the amount of scrap produced during MIM is minimal. However, this process relies on the plastic injection molding process where metals need to be mixed with binder materials then molded, with the binder material requiring to be sacrificed to yield the desired structures on the metal. That is, the binder material requires to be removed in a debinding step using solvent extraction or pyrolysis after the molding step. In addition, due to the current limitations of injection molding systems, resolution for MIM is also low. In fact, direct patterning on metal using MIM has not been achieved. In addition, metals such as aluminium and titanium that form a native oxide on the surface are not suitable for moulding by MIM as the removal step of the binder material such as pyrolysis and sintering may not lead to efficient densification of the green compact.

Further, care must be taken to tightly control the amount of shrinkage to achieve the required final shape in MIM. This means that the amount of binder used is crucial, and additional attention is required when using MIM to form intricate structures.

In microelectronics, electroplating is carried out where a template, usually a pre-structured polymer film, is required before the metal can be deposited. A sacrificial process involving the removal of the polymer template is also usually required.

Alternatively in lithography, substrates can be patterned with resist to deposit metal structures on the metal surface. However, this process also involves a sacrificial process of removing the resist, again limiting the resolution of the structures that can be formed on the metal surface.

The currently available methods for producing fine structures in metals are thus limited in terms of resolution and in the need to remove sacrificial materials to obtain the final structure. There is therefore a need to provide a method for making an imprint on a metal substrate that overcomes or at least ameliorates, one or more of the disadvantages described above.

### SUMMARY OF INVENTION

According to a first aspect, there is provided a method for making an imprint on a metal substrate comprising the steps of; (a) providing a mold having a defined imprint surface pattern in the nano-sized or micro-sized range; and (b) pressing the metal substrate against the mold at hot working temperature to form a nano-sized or micro-sized imprint thereon.

Advantageously, the method may enable the imprinting directly onto a metal substrate without the need for using sacrificial materials or any sacrificial processes. That is, the method may eliminate the extra processing steps of adding the sacrificial material and/or removing the sacrificial material, therefore speeding up the imprinting process and reducing waste that is formed from the imprinting process.

Further advantageously, the method may enable large surface area structuring of metals as well as metal films on substrates such as silicon, which is otherwise not possible with traditional techniques that require the use of sacrificial materials, such as photolithography and electron beam lithography.

Further advantageously, the structuring of the metal substrate may be carried out at hot-working temperatures. More advantageously, because the method may be carried out at hot-working temperatures, the method may not rely on extreme high temperatures. Additionally, the method may not require extremely high pressures or the use of sharp features on the mold to generate large localized pressures to enable metal flow. The method may enable the imprinting of nano-sized or micro-sized sharp and blunt features on the metal.

More advantageously, the method may be a combination of the principles of an imprinting process and principles of hot working in metallurgy. Advantageously, this may enable direct imprinting of structures on a metal substrate at high resolution on the micro- or nano-size range. Advantageously, this may overcome the issue of conventional techniques where micro- or nano-sized structures were not able to be directly imprinted on the metal substrate.

Further advantageously, the method may be useful in imparting hydrophobicity to naturally hydrophilic metal substrates. Advantageously, water contact angles of greater than about 130 degrees may be achieved by imprinting structures on metal substrates using the method.

According to a second aspect, there is provided a metal having a nano-sized or micro-sized range pattern imprinted thereon according to the method as defined above.

According to a third aspect, there is provided a hydrophobic metal comprising a metal surface having a nano-sized or micro-sized ranged pattern imprinted thereon according to the method as defined above.

### DEFINITIONS

The following words and terms used herein shall have the meaning indicated:

The term “hot-working”, for the purposes of this application, refers to processes where metals are plastically deformed above their recrystallization temperature. It is the process of metal forming that is carried out at temperatures close to melting where the yield stress of a metal is low and the metal becomes ‘softer’, thus amenable to shaping into desired forms.

The term “hot-working temperature”, for the purposes of this application, is the temperature in degrees Celsius (° C.), that is greater than 0.5 Tₘ, wherein the Tₘ is the melting point of the metal substrate in absolute temperature scale.

The term “sacrificial material”, for the purposes of this application, refers to any material that forms part of a substrate, which must be removed from the final product. The sacrificial material may be mixed into the substrate or deposited on the surface of the substrate. The sacrificial material may be part of the substrate from the beginning of the manufacturing process, or at any time during the manufacturing process, but may not be part of the final product.

The word “substantially” does not exclude “completely” e.g. a composition which is “substantially free” from Y may be completely free from Y. Where necessary, the word “substantially” may be omitted from the definition of the invention.

Unless specified otherwise, the terms “comprising” and “comprise”, and grammatical variants thereof, are intended to represent “open” or “inclusive” language such that they include recited elements but also permit inclusion of additional, unrecited elements.

As used herein, the term “about”, in the context of concentrations of components of the formulations, typically means +/−5% of the stated value, more typically +/−4% of the stated value, more typically +/−3% of the stated value, more typically, +/−2% of the stated value, even more typically +/−1% of the stated value, and even more typically +/−0.5% of the stated value.

Throughout this disclosure, certain embodiments may be disclosed in a range format. It should be understood that the description in range format is merely for convenience and brevity and should not be construed as an inflexible limitation on the scope of the disclosed ranges. Accordingly, the description of a range should be considered to have specifically disclosed all the possible sub-ranges as well as individual numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Certain embodiments may also be described broadly and generically herein. Each of the narrower species and subgeneric groupings falling within the generic disclosure also form part of the disclosure. This includes the generic description of the embodiments with a proviso or negative limitation removing any subject matter from the genus, regardless of whether or not the excised material is specifically recited herein.

### DETAILED DISCLOSURE OF EMBODIMENTS

Exemplary, non-limiting embodiments of the present invention will now be disclosed.

A method for making an imprint on a metal substrate may comprise the steps of: (a) providing a mold having a defined imprint surface pattern in the nano-sized or micro-sized range; and (b) pressing the metal substrate against the mold at hot working temperature to form a nano-sized or micro-sized imprint thereon.

The method may not comprise the use of a sacrificial material.

The sacrificial material may be selected from the group consisting of binder, resist, protective films and any combination thereof. The binder may be paraffin waxes, polymers or any mixture thereof.

The metal substrate may comprise a metal or metal alloy.

The metal may be selected from the group consisting of aluminium, gallium, indium, tin, bismuth, zinc, antimony, magnesium, calcium, strontium, barium, scandium, titanium, vanadium, chromium, manganese, iron, cobalt, nickel, copper, zinc, yttrium, zirconium, niobium, molybdenum, technetium, ruthenium, rhodium, palladium, silver, cadmium, lutetium, hafnium, tantalum, tungsten, rhenium, osmium, iridium, platinum, gold, lanthanum, cerium, praseodymium, neodymium, promethium, samarium, europium, gadolinium, terbium, ytterbium, and any mixture thereof.

The metal may be selected from the group consisting of gallium, indium, tin, bismuth, cadmium, lead, zinc, antimony, iron, nickel, cobalt, titanium, aluminium, magnesium and any mixture thereof.

The metal alloy may comprise metals and non-metals selected from the group consisting of aluminium, gallium, indium, tin, bismuth, zinc, antimony, magnesium, calcium, strontium, barium, scandium, titanium, vanadium, chromium, manganese, iron, cobalt, nickel, copper, zinc, yttrium, zirconium, niobium, molybdenum, carbon, boron, nitrogen, beryllium, technetium, ruthenium, rhodium, palladium, silver, cadmium, lutetium, hafnium, tantalum, tungsten, rhenium, osmium, iridium, platinum, gold, mercury, lanthanum, cerium, praseodymium, neodymium, promethium, samarium, europium, gadolinium, terbium, ytterbium, and any mixture thereof.

The metal alloy may comprise elements selected from the group consisting of bismuth, lead, tin, cadmium, indium and any mixture thereof. The metal or metal alloys in the composition may be advantageously chosen for their ease of hot-working.

The metal alloy may comprise 40 to 50 wt % bismuth, 20 to 30 wt % lead, 5 to 15 wt % tin, 0 to 12 wt % cadmium and 0 to 25 wt % indium, wherein the total wt % of bismuth, lead, tin, cadmium and indium combined is 100 wt %.

The metal alloy may comprise 43 to 46 wt % bismuth, 21 to 24 wt % lead, 7 to 10 wt % tin, 4 to 7 wt % cadmium and 18 to 21 wt % indium, wherein the total wt % of bismuth, lead, tin, cadmium and indium combined is 100 wt %.

The metal alloy may comprise 48 to 51 wt % bismuth, 21 to 24 wt % lead, 11 to 13 wt % tin and 20 to 22 wt % indium, wherein the total wt % of bismuth, lead, tin, cadmium and indium combined is 100 wt %.

The metal alloy may comprise 49 to 51 wt % bismuth, 25 to 28 wt % lead, 12 to 14 wt % tin and 9 to 11 wt % cadmium, wherein the total wt % of bismuth, lead, tin, cadmium and indium combined is 100 wt %.

The metal alloy may comprise 95 to 99 wt % indium and 1 to 5 wt % silver, wherein the total wt % of indium and silver combined is 100 wt %.

The metal alloy may comprise 40 to 60 wt % indium and 40 to 60 wt % tin, wherein the total wt % of indium and tin combined is 100%.

The metal alloy may comprise 50 to 70 wt % tin, 35 to 45 wt % lead and 0.5 to 2 wt % antimony, wherein the total wt % of tin, lead and antimony combined is 100%.

The metal substrate may be supported on a silicon substrate.

The metal substrate may be deposited on the silicon substrate by a method selected from the group consisting of sputtering, melt deposition, thermal evaporation and a combination thereof.

The pressing step may be performed at a pressure in the range of about 40 bars to about 60 bars, about 40 bars to about 45 bars, about 40 bars to about 50 bars, about 40 bars to about 55 bars, about 45 bars to about 50 bars, about 45 bars to about 55 bars, about 45 bars to about 60 bars, about 50 bars to about 55 bars, about 50 bars to about 60 bars about 55 bars to about 60 bars, about 40 bars to about 250 bars, about 40 bars to about 80 bars, about 40 bars to about 120 bars, about 40 bars to about 150 bars, about 40 bars to about 200 bars, about 80 bars to about 120 bars, about 80 bars to about 150 bars, about 80 bars to about 200 bars, about 80 bars to about 250 bars, about 120 bars to about 150 bars, about 120 bars to about 200 bars, about 120 bars to about 250 bars, about 150 bars to about 200 bars, about 150 bars to about 250 bars or about 200 bars to about 250 bars.

The hot working temperature, in degrees Celsius (° C.), may be greater than 0.5 Tₘ, wherein the Tₘ is the melting point of the metal substrate in absolute temperature scale.

The pressing step may be undertaken at temperature approximating 0.5 Tₘ of the particular metal or metal alloy substrate. For instance, the pressing temperature may be around ±50° C., ±45° C., ±40° C., ±35° C., ±30° C., ±25° C.±20° C., ±15° C.±10° C., ±5° C. or ±1° C. of the hot working temperature.

The hot working temperature may be in the range of about 5° C. to about 1300° C., about 5° C. to about 10° C., about 5° C. to about 20° C., about 5° C. to about 50° C., about 5° C. to about 100° C., about 5° C. to about 200° C., about 5° C. to about 400° C., about 5° C. to about 450° C., about 5° C. to about 600° C., about 5° C. to about 1000° C., about 10° C. to about 20° C., about 10° C. to about 50° C., about 10° C. to about 100° C., about 10° C. to about 200° C., about 10° C. to about 450° C., about 10° C. to about 600° C., about 10° C. to about 1000° C., about 10° C. to about 1300° C., about 20° C. to about 50° C., about 20° C. to about 100° C., about 20° C. to about 200° C., about 20° C. to about 450° C., about 20° C. to about 600° C., about 20° C. to about 1000° C., about 20° C. to about 1300° C., about 50° C. to about 100° C., about 50° C. to about 200° C., about 50° C. to about 450° C., about 50° C. to about 600° C., about 50° C. to about 1000° C., about 50° C. to about 1300° C., about 100° C. to about 200° C., about 100° C. to about 450° C., about 100° C. to about 600° C., about 100° C. to about 1000° C., about 100° C. to about 1300° C., about 200° C. to about 450° C., about 200° C. to about 600° C., about 200° C. to about 1000° C., about 200° C. to about 1300° C., about 450° C. to about 600° C., about 450° C. to about 1000° C., about 450° C. to about 1300° C., about 600° C. to about 1000° C., about 600° C. to about 1300° C. or about 1000° C. to about 1300° C.

The pressing step may be performed under any combination of temperature and pressure conditions disclosed herein. The pressing step may be undertaken at conditions suitable to modify a mechanical property of said metal substrate. For instance, the pressing step may comprise converting at least a part of or the entire metal substrate into a flowable or deformable state. The pressing step may comprise conforming the flowable metal substrate to a patterned surface of the mold. For instance, the pressing step may comprise flowing the deformed metal substrate over, across or around nanofeatures or microfeatures (e.g. pillars and dots) on the mold The pressing step may also comprise conveying or flowing deformed metal substrate into recesses (e.g., slits, trenches, holes) disposed along or present on the patterned mold surface. Advantageously, the pressing step may result in the provision of a desired topography on the metal substrate after a subsequent cooling step. Advantageously, the topography may be selected to confer hydrophobic properties to said metal substrate.

Prior to the pressing step, the surface of the metal substrate may be flattened to achieve a substantially uniform or flat surface. Advantageously, this may allow the metal substrate to more uniformly conform to the patterned mold surface during the subsequent pressing step. This flattening step may comprise a pre-heating step whereby the metal substrate is heated to its melting point or higher and thereafter applying a pressure sufficient to flatten said metal substrate.

The method may be performed under an inert atmosphere. The inert atmosphere may be a nitrogen atmosphere or an argon atmosphere. The method may be performed under a reducing atmosphere. The reducing atmosphere may be a gas mixture comprising a small amount of hydrogen. The hydrogen may be present in the range of about 2% to about 10%, about 2% to about 5%, about 2% to about 7%, about 5% to about 7%, about 5% to about 10% or about 7% to about 10% of the gas mixture.

The mold may be made of a mold material selected from the group consisting of nickel, palladium, platinum, iron, steel, cobalt, tungsten, molybdenum, tantalum, high carbon steel, nickel-titanium-aluminium alloys, graphitic carbon, glassy carbon, silicon carbide, silicon nitride, cermets and any mixture thereof.

The mold may further comprise a coating of 1H,1H,2H,2H-perfluorodecyltrichlorosilane, diamond-like carbon or graphitic carbon. The coating may have a thickness in the range of about 5 nm to about 10 μm, about 5 nm to about 10 nm, about 5 nm to about 50 nm, about 5 nm to about 100 nm, about 5 nm to about 500 nm, about 5 nm to about 1 μm, about 5 nm to about 5 μm, about 10 nm to about 50 nm, about 10 nm to about 100 nm, about 10 nm to about 500 nm, about 10 nm to about 1 μm, about 10 nm to about 5 μm, about 10 nm to about 10 μm, about 50 nm to about 100 nm, about 50 nm to about 500 nm, about 50 nm to about 1 μm, about 50 nm to about 5 μm, about 50 nm to about 10 μm, about 100 nm to about 500 nm, about 100 nm to about 1 μm, about 500 nm to about 5 μm, about 500 nm to about 10 μm, about 1 μm to about 5 μm, about 1 μm to about 10 μm or about 5 μm to about 10 μm.

The coating may facilitate easy removal of the mold from the imprinted material.

The structure may be selected from the group consisting of a hemisphere, pillar, trench, cone, prism and pyramid.

The hemisphere may be half of a sphere. The sphere may be a solid formed by a set of points that are all the same distance from a given point in three-dimensional space. The hemisphere may be a hole, dot or dome.

The pillar may be a cylinder. The cylinder may be a solid formed by the points at a fixed distance from a given line segment that is the axis of the cylinder, and two planes (base faces) perpendicular to this axis. All cross-sections parallel to the base faces may be the same. The cross-section may be a circle, ellipse, parabola or hyperbola. The cylinder may be a right circle cylinder, elliptic cylinder, parabolic cylinder or hyperbolic cylinder.

The trench may be a long ditch having a sidewall and bottom. The bottom of the trench may be lower than the plane of the surface. The trench may have a parallel cross-section having a shape selected from the group consisting of circle, semicircle, oblique circle, and polygon.

The cone may be a solid formed by a base in a plane and by a surface (lateral surface) formed by the locus of all straight line segments joining the apex to the perimeter of the base. The base may be a circle or ellipse. The cone may be a right circular cone or oblique circular cone.

The prism may be a solid formed by an n-sided polygonal base, a translated copy (not in the same plane as the first) and n other faces joining the corresponding sides of the two bases. The prism may be a right prism in which the joining edges and faces are perpendicular to the base faces. The prism may be an oblique prism where the joining edges and the faces are not perpendicular to the base faces. All cross-sections parallel to the base faces may be the same. The cross-section may be a polygon. The polygon may be any n-gon. The polygon may be a triangle, quadrilateral, pentagon, hexagon, heptagon, octagon, nonagon, decagon, hendecagon, dodecagon, pentadecagon, icosagon, hectagon, chiliagon, myriagon or megagon.

The polygon may be any regular n-gon that is equiangular and equilateral. The polygon may be an equilateral triangle, square, regular pentagon, regular hexagon, regular heptagon, regular octagon, regular nonagon, regular decagon, regular hendecagon, regular dodecagon, regular pentadecagon, regular icosagon, regular hectagon, regular chiliagon, regular myriagon or regular megagon.

The structure may be a hemiellipsoid.

The structures may be hierarchical. The structures may be imprinted on top of each other. The structures may be overlayed onto each other.

The structure may be hollow and embedded in the surface of the metal substrate.

The structure may be solid and protruding from the surface of the metal substrate.

The structure may have a width of less than 1 μm. The structure may have a width of less than 500 nm.

The structure may have a height of less than 1 μm. The structure may have a height of less than 500 nm.

The structure may have an aspect ratio in the range of about 1 to about 5, about 1 to about 1.5, about 1 to about 2, about 1 to about 2.5, 1 to about 3, about 1 to about 3.5, about 1 to about 4. About 1 to about 4.5, about 1.5 to about 2, about 1.5 to about 2.5, about 1.5 to about 3, about 1.5 to about 3.5, about 1.5 to about 4, about 1.5 to about 4.5, about 1.5 to about 5, about 2 to about 2.5, about 2 to about 3, about 2 to about 3.5, about 2 to about 4, about 2 to about 4.5, about 2 to about 5, about 2.5 to about 3, about 2.5 to about 3.5, about 2.5 to about 4, about 2.5 to about 5, about 3 to about 3.5, about 3 to about 4, about 3 to about 4.5, about 3 to about 5, about 3.5 to about 4, about 3.5 to about 4.5, about 3.5 to about 5, about 4 to about 4.5, about 4 to about 5 or about 4.5 to about 5.

The centre-to-centre feature distance (the distance between the centre of two features) may be in the range of about 50 nm to about 1.5 μm, about 50 nm to about 100 nm, about 50 nm to about 200 nm, about 50 nm to about 500 nm, about 50 nm to about 1 μm, about 100 nm to about 200 nm, about 100 nm to about 500 nm, about 100 nm to about 1 μm, about 100 nm to about 1.5 μm, about 200 nm to about 500 nm, about 200 nm to about 1 μm, about 200 nm to about 1.5 μm, about 500 nm to about 1 μm, about 500 nm to about 1.5 μm or about 1 μm to about 1.5 μm.

The method may further comprise the step of removing the mold from the metal substrate after the contacting step.

In another aspect, the disclosure relates to a metal having a nano-sized or micro-sized range pattern imprinted thereon according to the method disclosed herein.

In yet another aspect, the disclosure relates to a hydrophobic metal comprising a metal surface having a nano-sized or micro-sized ranged pattern imprinted thereon according to the method disclosed herein.

The hydrophobic metal may have a water contact angle greater than about 150 degrees, greater than about 140 degrees, greater than about 135 degrees, greater than about 130 degrees, greater than about 125 degrees, greater than about 120 degrees, greater than about 115 degrees, greater than about 110 degrees, greater than about 105 degrees, greater than about 100 degrees, greater than about 95 degrees or greater than about 90 degrees.

Advantageously, the present disclosure provides a useful method for fabricating hydrophobic or ultra-hydrophobic metal textured-surfaces. Importantly, the process avoids the need for conventional lithography steps or laser-etching steps.

### BRIEF DESCRIPTION OF DRAWINGS

The accompanying drawings illustrate a disclosed embodiment and serves to explain the principles of the disclosed embodiment. It is to be understood, however, that the drawings are designed for purposes of illustration only, and not as a definition of the limits of the invention.

FIG. 1 refers to SEM images of Indium imprinted with (A) holes, (B) lines and (C) pillars.

FIG. 2 refers to SEM images of Alloy A imprinted with (A) holes, (B) lines and (C) pillars.

FIG. 3 refers to SEM images of Alloy B imprinted with holes at (A) 2000×, (B) 10,000× and (C) pillars with 15,000× magnification.

FIG. 4 refers to SEM images of Alloy C imprinted with holes at (A) 10,000× and (B) 30,000× magnification.

FIG. 5 refers to SEM images of Alloy D imprinted with 500 nm diameter holes at 20,000× magnification.

FIG. 6 refers to SEM images of Alloy E imprinted with 500 nm diameter holes at (A) 10,000× and (B) 20,000× magnification.

### EXAMPLES

Non-limiting examples of the invention and a comparative example will be further described in greater detail by reference to specific examples, which should not be construed as in any way limiting the scope of the invention.

### Example 1: The Imprinting Process

### General Method

Low melting-point pure metals such as indium and various alloys (see Table 1) in the form of ingots and sheets (0.25-1.0 mm thickness) were purchased from CS Alloys, Gastonia, N.C. (USA), Goodfellow (UK) or Sigma-Aldrich (Singapore). The sheets were used as is without further modification. Ingots were cast into free standing sheets (0.5 mm thick), or sputtered or melt deposited onto a silicon wafer which was used as a support. When required, the metal film was heated to below melting-point and a certain pressure was applied on the surface to flatten the film surface A flat nickel piece was used as a mold.

A pre-cleaned nickel mold, fabricated in-house was pressed against this metallic or alloy film supported on silicon at a pressure of 50 bars in an Obducat thermal nanoprinter, leading to the reverse tone transfer of the mold topography into the film. The operating temperatures of different metals and alloys are shown in Table 1. After imprinting for 10 minutes, the sample was cooled to room temperature for demolding. After removal of the mold, the replicated patterns appeared on the films. 100% yields of the metals were obtained after the demolding step.

The nickel mold was fabricated using a nickel electroforming technique. Firstly, a replica was made on a polycarbonate sheet using a mother mold using nanoimprint lithography. This polycarbonate replica was sputter-coated with a thin film of metal. Electroforming was then carried out to make a negative of the polycarbonate replica that was then used as a nickel mold for metal imprinting.

Melting Point and Imprinting Temperature of Metal and Alloys

Table 1 below shows some examples of metal substrates that may be imprinted using the process disclosed herein. The table shows the composition of the metal substrate as well as the melting point and imprinting temperature of the metal substrate.

Table 1. The melting point and imprinting temperature of some metal substrates

TABLE 1

| | | Melting point | Imprinting tem- |
|---|---|---|---|
| Metal substrate | Composition (%) | (° C.) | perature (° C.) |
| Indium | Indium: 99.99 | 156.6 | 154 |
| Alloy A | Bismuth: 44.7 | 47.2 | 45 |
| | Lead: 22.6 | | |
| | Tin: 8.3 | | |
| | Cadmium: 5.3 | | |
| | Indium: 19.1 | | |
| Alloy B | Bismuth: 49.0 | 57.8 | 56 |
| | Lead: 22.6 | | |
| | Tin: 12.0 | | |
| | Indium: 21.0 | | |
| Alloy C | Bismuth: 50.0 | 70 | 68 |
| | Lead: 26.67 | | |
| | Tin: 13.3 | | |
| | Indium: 10.0 | | |
| Alloy D | Indium: 97 | 143 | 140 |
| | Silver: 3 | | |
| Alloy E | Indium: 50 | 118-125 | 115 |
| | Tin: 50 | | |
| Alloy F | Tin: 60 | 183 | 178 |
| | Lead: 39 | | |
| | Antimony: 1 | | |

Alloys A, B and C are “Low 117”, “Low 136” and “Bend 158”, respectively, purchased from CS Alloys, Gastonia, N.C. (USA). Alloys D, E, F are purchased from Aldrich.

### Example 2: SEM Characterization

The imprinted films were subsequently characterized by a scanning electron microscope (JEOL FEG-SEM 6700). The imaging was done under vacuum without coating the samples with a conducting metal layer.

### Indium

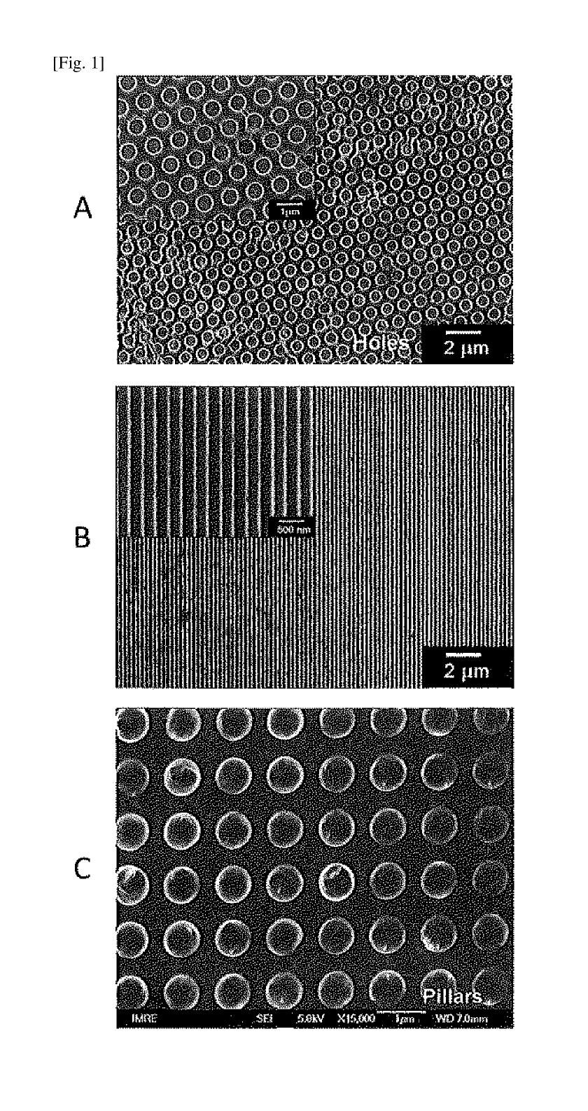

FIG. 1 refers to SEM images of Indium imprinted with (A) 500 nm diameter holes, (B) 250 nm width lines and (C) 500 nm diameter pillars.

### Alloy A

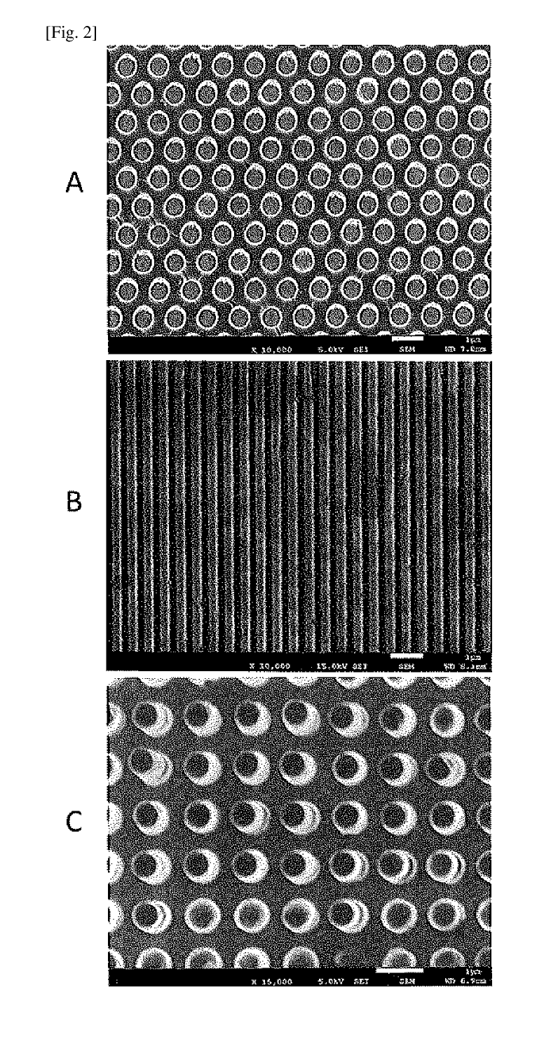

FIG. 2 refers to SEM images of Alloy A imprinted with (A) 500 nm diameter holes, (B) 250 nm width lines and (C) 500 nm diameter pillars.

### Alloy B

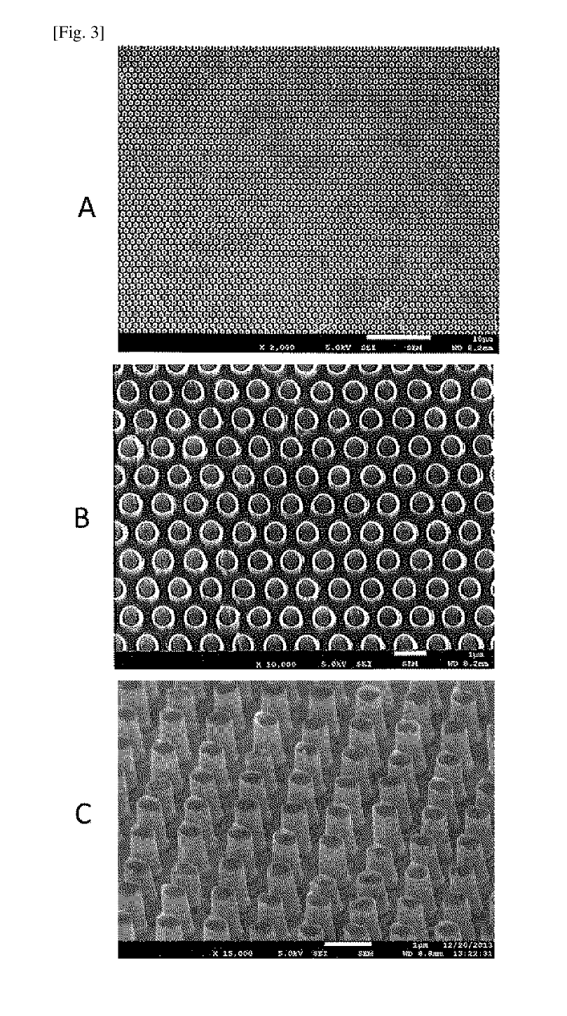

FIG. 3 refers to SEM images of Alloy B imprinted with (A) 500 nm diameter holes at 2,000× magnification, (B) 500 nm diameter holes at 10,000× magnification and (C) 500 nm diameter pillars at 15,000× magnification.

### Alloy C

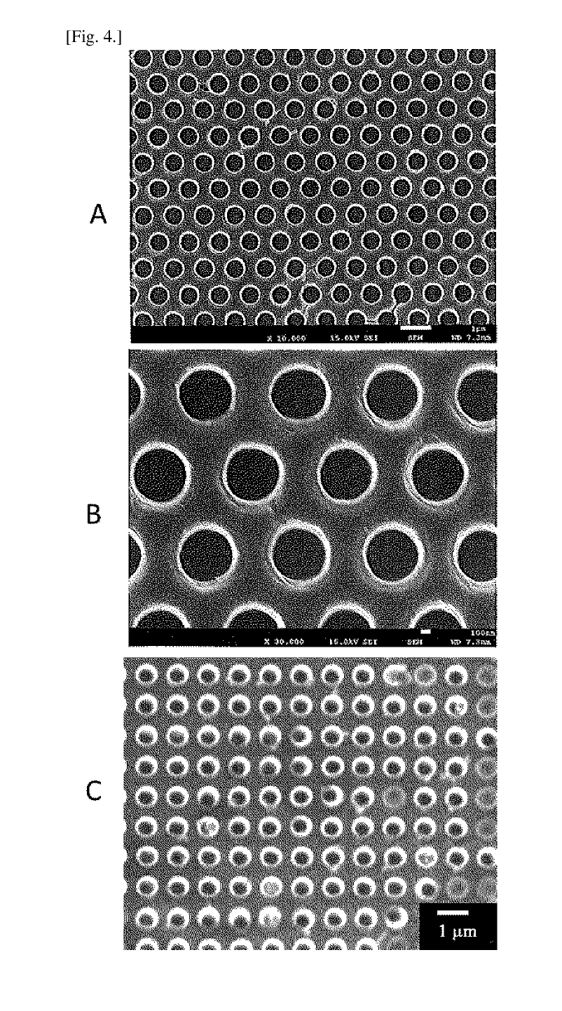

FIG. 4 refers to SEM images of Alloy C imprinted with (A) 500 nm diameter holes at 10,000× magnification, (B) 500 nm diameter holes at 30,000× magnification and (C) pillars at 10,000× magnification.

### Alloy D

FIG. 5 refers to SEM images of Alloy D imprinted with 500 nm diameter holes at 20,000× magnification.

### Alloy E

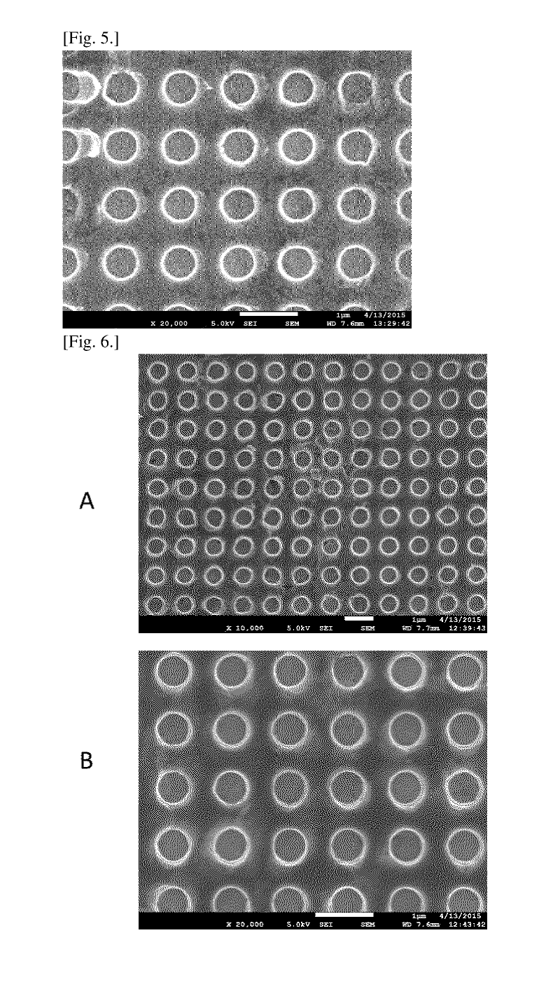

FIG. 6 refers to SEM images of Alloy E imprinted with 500 nm diameter holes at (A) 10,000× and (B) 20,000× magnification.

### Example 3: Contact Angle

The water contact angles of the films were measured using contact angle goniometer (Rame-Hart). The sample was mounted on a flat holder. A drop of water was then dropped on the surface using a syringe. A live video image of the sample was obtained. The light and focus was adjusted to get a sharp image of the water drop. The water contact angle was automatically measured from the image using the goniometer. The water contact angle was calculated as the average value of three measurements.

Table 2. The contact angles of metal substrates having different patterns.

TABLE 2

| | | Mean contact angle |
|---|---|---|
| Metal substrate | Surface condition | (degree) |
| Indium | Flat | 88.1 |
| | Holes | 114.9 |
| | Pillars | 105.8 |
| Alloy A | Flat | 90.6 |
| | Holes | 110.3 |
| | Pillars | 131.6 |
| Alloy B | Flat | 80.4 |
| | Holes | 102.3 |
| | Pillars | 133.8 |
| Alloy C | Flat | 81.4 |
| | Holes | 107.5 |
| | Pillars | 110.5 |

It can be seen from Table 2 that the imprinted patterns can increase the surface hydrophobicity of metals which are naturally hydrophilic. It was also found that to achieve an even greater contact angles, the dimensions of the patterns may be modified.

### INDUSTRIAL APPLICABILITY

The method may be used to make precision engineered components. The method may also be used to impart hydrophobicity to metals and alloys such as steel. Making metals and alloys hydrophobic may prevent its corrosion. The method may also be used to impart iridescent property to metals to improve their aesthetics. The method may also be used to imparting combination of hydrophobicity and iridescent properties to the metals.

It will be apparent that various other modifications and adaptations of the invention will be apparent to the person skilled in the art after reading the foregoing disclosure without departing from the spirit and scope of the invention and it is intended that all such modifications and adaptations come within the scope of the appended claims.

1. A method for making an imprint on a metal substrate comprising the steps of:
(a) providing a mold having a defined imprint surface pattern in the nano-sized or micro-sized range; and
(b) pressing the metal substrate against the mold at hot working temperature to form a nano-sized or micro-sized imprint thereon, wherein the hot working temperature, in degrees Celsius (° C.), is greater than 0.5 Tₘ, wherein the Tₘ is the melting point of the metal substrate in absolute temperature scale.

2. The method of claim 1, wherein the method does not comprise the use of a sacrificial material.

3. The method of claim 2, wherein the sacrificial material may be selected from the group consisting of binder, resist, protective films and any combination thereof.

4. The method of claim 1, wherein the metal substrate comprises a metal or metal alloy.

5. The method of claim 4, wherein the metal is selected from the group consisting of gallium, indium, tin, bismuth, cadmium, lead, zinc, silver, antimony, iron, nickel, cobalt, titanium, aluminium, magnesium and any mixture thereof.

6. (canceled)

7. The method of claim 5, wherein the metal alloy comprises 40 to 50 wt % bismuth, 20 to 30 wt % lead, 5 to 15 wt % tin, 0 to 12 wt % cadmium and 0 to 25 wt % indium, wherein the total wt % of bismuth, lead, tin, cadmium and indium combined is 100 wt %.

8. The method of claim 1, wherein the metal substrate is supported on a silicon substrate.

9. The method of claim 8, wherein the metal substrate is deposited on the silicon substrate by a method selected from the group consisting of sputtering, melt deposition, thermal evaporation and a combination thereof.

10. The method of claim 1, wherein the pressing step is performed at a pressure in the range of 40 to 250 bars or wherein the hot working temperature is in the range of 5° C. to 1300° C.

11. (canceled)

12. (canceled)

13. The method of claim 1, wherein the method is performed under an inert atmosphere or a reducing atmosphere or a nitrogen atmosphere or argon atmosphere or a reducing atmosphere consisting of small amount of hydrogen gas.

14. (canceled)

15. The method of claim 1, wherein the mold is made of a mold material selected from the group consisting of nickel, palladium, platinum, iron, steel, cobalt, tungsten, molybdenum, tantalum, high carbon steel, nickel-titanium-aluminium alloys, graphitic carbon, glassy carbon, silicon carbide, silicon nitride, cermets and any mixture thereof.

16. The method of claim 15, wherein the mold further comprises a coating of 1H,1H,2H,2H-perfluorodecyltrichlorosilane, diamond-like carbon or graphitic carbon.

17. The method of claim 1, wherein the structure is selected from the group consisting of a hemisphere, pillar, trench, cone, prism and pyramid.

18. The method of claim 17, wherein the structures are hierarchical.

19. The method of claim 17, wherein the structure is hollow and embedded in the surface of the metal substrate or the structure is solid and protruding from the surface of the metal substrate.

20. (canceled)

21. The method of claim 17, wherein the structure has a width of less than 1 μm or a width of less than 500 nm or a height of less than 1 μm or an aspect ratio in the range of 1 to 3.

22.-24. (canceled)

25. The method of claim 1, further comprising the step of removing the mold from the metal substrate after the pressing step.

26. A metal having a nano-sized or micro-sized range pattern imprinted thereon according to the method of claim 1.

27. A hydrophobic metal comprising a metal surface having a nano-sized or micro-sized ranged pattern imprinted thereon according to the method of claim 1.
